(19) United States
(12) Patent Application Publication
(10) Pub. No.: US 2026/0343799 A1
(43) Pub. Date: Oct. 29, 2026

(54) HEAT DISSIPATION APPARATUS AND CHIP CO-PACKAGING SYSTEM

(71) Applicant: Micas Networks Inc., SAN JOSE, CA (US)

(72) Inventors: Wei LIU, San Jose, CA (US); Guohong LAI, San Jose, CA (US)

(73) Assignee: Micas Networks Inc., SAN JOSE, CA (US)

(21) Appl. No.: 19/708,664

(22) Filed: Jun. 15, 2026

Related U.S. Application Data
(63) Continuation of application No. PCT/CN2026/083986, filed on Mar. 17, 2026.

(30) Foreign Application Priority Data
Apr. 2, 2025 (CN) 202510405432.9

(51) Int. Cl. H05K 7/20; H05K 1/02

(52) U.S. Cl. CPC H05K 7/20254; H05K 1/0203; H05K 7/20272

(57) ABSTRACT

This application relates to a heat dissipation apparatus and a chip co-packaging system, including a cold plate in thermal contact with a first heat-generating component and a second heat-generating component. The cold plate includes: a first heat dissipation portion, provided with a liquid inlet, where the liquid inlet is configured to inject a coolant into the first heat dissipation portion to dissipate heat from the first heat-generating component; and a second heat dissipation portion, which is in fluid communication with the first heat dissipation portion and is provided with a liquid outlet, where the second heat dissipation portion is configured to receive the coolant from the first heat dissipation portion to dissipate heat from the second heat-generating component, and to discharge the coolant from the liquid outlet.

### CROSS-REFERENCE TO RELATED APPLICATIONS

This application is a continuation of International Application No. PCT/CN 2026/083986, filed on 17. Mar. 2026, which claims priority to Chinese Patent Application No. 202510405432.9, filed with the China National Intellectual Property Administration on Apr. 2, 2025 and entitled “HEAT DISSIPATION APPARATUS AND CHIP CO-PACKAGING SYSTEM”, both of which are incorporated herein by reference in their entireties.

### TECHNICAL FIELD

This application relates to the technical field of heat dissipation for electronic devices, and in particular, to a heat dissipation apparatus and a chip co-packaging system.

### BACKGROUND

A co-packaged optics (Co-packaged Optics, CPO) technology can shorten a distance between a switching chip and an optical chip and integrate the two chips on a same substrate, thereby reducing an interconnection distance and achieving high-speed signal transmission and low system power consumption. However, in the CPO technology, continuously reducing the interconnection distance between the high-power switching chip and the optical chip or integrating the two chips on the same substrate inevitably leads to a thermal crosstalk problem, especially because the optical chip is highly temperature-sensitive.

### SUMMARY

Embodiments of this application provide a heat dissipation apparatus and a chip co-packaging system.

According to a first aspect, an embodiment of this application first provides a heat dissipation apparatus for dissipating heat from a first heat-generating component and a second heat-generating component disposed on a substrate, where a maximum allowable temperature of the first heat-generating component is lower than a maximum allowable temperature of the second heat-generating component; and the heat dissipation apparatus includes:
a cold plate in thermal contact with the first heat-generating component and the second heat-generating component, where the cold plate includes:
a first heat dissipation portion, provided with a liquid inlet, where the liquid inlet is configured to inject a coolant into the first heat dissipation portion to dissipate heat from the first heat-generating component; and
a second heat dissipation portion, which is in fluid communication with the first heat dissipation portion and is provided with a liquid outlet, where the second heat dissipation portion is configured to receive the coolant from the first heat dissipation portion to dissipate heat from the second heat-generating component, and to discharge the coolant from the liquid outlet.

In an embodiment, a first liquid chamber is formed inside the first heat dissipation portion, a second liquid chamber is formed inside the second heat dissipation portion, and the first liquid chamber and the second liquid chamber are in fluid communication with each other; and
the liquid inlet allows the coolant to flow into the first liquid chamber, and the liquid outlet allows the coolant to flow out of the second liquid chamber.

In an embodiment, the cold plate includes a first sub-cold plate and a second sub-cold plate, and a partition member is disposed between the first sub-cold plate and the second sub-cold plate;
the first sub-cold plate includes the first liquid chamber and the second liquid chamber, the first sub-cold plate is correspondingly provided with a first liquid inlet and a first liquid outlet, the first liquid inlet allows the coolant to flow into the first liquid chamber, and the first liquid outlet allows the coolant to flow out of the second liquid chamber; and
the second sub-cold plate includes a third liquid chamber and a fourth liquid chamber, the third liquid chamber and the fourth liquid chamber are in fluid communication with each other, the second sub-cold plate is correspondingly provided with a second liquid inlet and a second liquid outlet, the second liquid inlet allows the coolant to flow into the third liquid chamber, and the second liquid outlet allows the coolant to flow out of the fourth liquid chamber.

In an embodiment, the partition member includes at least two partition plates, and two adjacent partition plates and a side wall of the cold plate enclose a thermal insulation chamber.

In an embodiment, the first liquid inlet is disposed on at least one of a side of the first sub-cold plate facing away from the substrate or a side adjacent to the substrate; and/or the second liquid inlet is disposed on at least one of a side of the second sub-cold plate facing away from the substrate or a side adjacent to the substrate; and/or
the first liquid outlet is disposed on at least one of the side of the first sub-cold plate facing away from the substrate or the side adjacent to the substrate; and/or
the second liquid outlet is disposed on at least one of the side of the second sub-cold plate facing away from the substrate or the side adjacent to the substrate.

In an embodiment, at least one baffle plate is disposed between the first liquid chamber and the second liquid chamber, and the at least one baffle plate is configured to form a flow path of the coolant from the first liquid chamber to the second liquid chamber.

In an embodiment, the heat dissipation apparatus further includes a flow guiding plate, and the flow guiding plate is disposed inside the cold plate along a preset path to divide space inside the cold plate into the first liquid chamber and the second liquid chamber,
where the first liquid chamber is located at an outer periphery of the second liquid chamber.

In an embodiment, the heat dissipation apparatus further comprises a flow guiding plate the flow guiding plate is disposed inside the cold plate along a preset path to divide space inside the cold plate into the first liquid chamber and the second liquid chamber, wherein the first liquid chamber is located at an outer periphery of the second liquid chamber.

In an embodiment, the flow guiding plate comprises a starting end, a connecting portion and a trailing end, the starting end is connected to an inner wall of the cold plate, the connecting portion connects the starting end and the trailing end, the flow guiding plate is configured to allow the coolant to spirally flow from the starting end to the trailing end through the connecting portion, and flow into the second liquid chamber at the trailing end.

In an embodiment, the flow guiding plate spirally extends around a center of the cold plate.

In an embodiment, the flow guiding plate includes a starting end and a trailing end, the starting end is connected to an inner wall of the cold plate, and the trailing end spirally deflects around a center of the cold plate; and
the coolant spirally flows from the starting end to the trailing end, and flows into the second liquid chamber at the trailing end.

In an embodiment, the liquid inlet is disposed on at least one of a side wall of the cold plate close to the starting end of the flow guiding plate or a surface of the cold plate facing away from the substrate; and
the liquid outlet is disposed on the surface of the cold plate facing away from the substrate.

In an embodiment, the heat dissipation apparatus further includes a heat sink, and the heat sink is located in the first liquid chamber and/or the second liquid chamber; and
the heat sink is disposed on a side wall of the cold plate close to the substrate.

In an embodiment, a surface of the cold plate facing toward the substrate is a flat surface, where the cold plate abuts against the first heat-generating component, and the cold plate is in thermal contact with the second heat-generating component through a heat-conducting member; or the cold plate abuts against the second heat-generating component, and the cold plate is in thermal contact with the first heat-generating component through a heat-conducting member; and/or
a surface of the cold plate facing toward the substrate is a stepped surface, so that the cold plate abuts against the first heat-generating component and the second heat-generating component.

In an embodiment, an orthographic projection of the first liquid chamber on the substrate at least partially covers an orthographic projection of the first heat-generating component on the substrate, and an orthographic projection of the second liquid chamber on the substrate at least partially covers an orthographic projection of the second heat-generating component on the substrate.

According to a second aspect, an embodiment of this application further provides a chip co-packaging system, including:
at least one electronic device, where the electronic device includes a substrate, a first heat-generating component, and a second heat-generating component, the first heat-generating component and the second heat-generating component are integrated on the substrate, a maximum allowable temperature of the first heat-generating component is lower than a maximum allowable temperature of the second heat-generating component, and the temperature includes a junction temperature or a case temperature; and
the heat dissipation apparatus in the foregoing embodiment, where the heat dissipation apparatus is located on a side of the first heat-generating component and the second heat-generating component facing away from the substrate and is in thermal contact with the first heat-generating component and the second heat-generating component, and a coolant in the heat dissipation apparatus sequentially flows through the first heat-generating component and the second heat-generating component.

The heat dissipation apparatus and the chip co-packaging system ensure effective heat conduction by bringing the cold plate into close thermal contact with the first heat-generating component and the second heat-generating component. Furthermore, the first heat dissipation portion and the second heat dissipation portion in fluid communication with each other are disposed inside the cold plate. The coolant flows from the liquid inlet into the first heat dissipation portion. In the first heat dissipation portion, the coolant fully absorbs heat emitted by the first heat-generating component. After absorbing the heat, the coolant subsequently flows into the second heat dissipation portion. In the second heat dissipation portion, the coolant continues to absorb heat emitted by the second heat-generating component, and then the temperature-increased coolant flows out of the liquid outlet. This arrangement enables the coolant to preferentially cool the more temperature-sensitive first heat-generating component, ensures that the first heat-generating component is in a low-temperature environment, and stabilizes signal quality of the first heat-generating component, thereby improving data transmission performance of the electronic device. In addition, this arrangement can effectively prevent thermal crosstalk-induced overheating of the first heat-generating component caused by the heat emitted by the second heat-generating component, and can also achieve effective heat dissipation of the second heat-generating component while ensuring performance of the first heat-generating component, thereby helping improve heat dissipation efficiency of the electronic device.

### BRIEF DESCRIPTION OF DRAWINGS

The accompanying drawings herein are incorporated into this specification and form a part of this specification. They illustrate embodiments conforming to this application and are intended to explain the principles of this application together with this specification.

FIG. 1 is a schematic diagram of a heat dissipation principle of a heat dissipation apparatus according to some embodiments of this application.

FIG. 2 is a schematic diagram of a heat dissipation principle of a first sub-cold plate and a second sub-cold plate according to some embodiments of this application.

FIG. 3 is a schematic diagram of an overall structure of a heat dissipation apparatus according to some embodiments of this application.

FIG. 4 is a schematic exploded view of a heat dissipation apparatus and a substrate according to some embodiments of this application.

FIG. 5 is a schematic diagram of a structure of a correspondence between a first sub-cold plate, a second sub-cold plate, and a substrate according to some embodiments of this application.

FIG. 6 is a schematic side view of a structure of a cold plate and a substrate according to some embodiments of this application.

FIG. 7 is a schematic diagram of a structure of a partition member in a cold plate according to some embodiments of this application.

FIG. 8 is a schematic diagram of a structure of a heat dissipation apparatus connected to a flow regulating valve and a flow rate controller according to some embodiments of this application.

FIG. 9 is a schematic diagram of a structure of a plurality of liquid inlets and a plurality of liquid outlets in a cold plate according to some embodiments of this application.

FIG. 10 is a schematic diagram of a structure of a baffle plate in a cold plate according to some embodiments of this application.

FIG. 11 is a schematic diagram of a structure of a heat sink in a cold plate according to some embodiments of this application.

FIG. 12 is a schematic diagram of a structure of a heat sink and a baffle plate in a cold plate according to some embodiments of this application.

FIG. 13 is a schematic diagram of a heat dissipation principle of a heat dissipation apparatus according to some other embodiments of this application.

FIG. 14 is a schematic diagram of an overall structure of a heat dissipation apparatus according to some other embodiments of this application.

FIG. 15 is a schematic exploded view of a structure of a heat dissipation apparatus according to some other embodiments of this application.

FIG. 16 is a schematic top view of a structure of a cold plate after an upper cover is removed according to some other embodiments of this application.

FIG. 17 is a schematic diagram of a structure of a plurality of liquid inlets in a cold plate according to some other embodiments of this application.

### REFERENCE NUMERALS:

10. substrate; 11. first substrate; 12. second substrate; 20. first heat-generating component; 30. second heat-generating component; 40. thermally conductive medium;
300. cold plate; 310. first heat dissipation portion; 311. first liquid chamber; 312. third liquid chamber; 320. second heat dissipation portion; 321. second liquid chamber; 322. fourth liquid chamber; 301. liquid inlet; 3011. first liquid inlet; 3012. second liquid inlet; 302. liquid outlet; 3021. first liquid outlet; 3022. second liquid outlet; 330. partition member; 331. partition plate; 3301. thermal insulation chamber; 340. first sub-cold plate; 350. second sub-cold plate; 360. baffle plate; 370. heat sink; 380. flow guiding plate; 381. starting end; 382. trailing end; 383. first flow guiding plate; 384. second flow guiding plate; 385. third flow guiding plate; 386. fourth flow guiding plate; 387. connecting portion;
400. flow regulating valve;
500. flow rate controller.

### DESCRIPTION OF EMBODIMENTS

To make the objectives, features, and advantages of this application more apparent and more readily understandable, the following describes specific implementations of this application in detail with reference to the accompanying drawings. In the following description, many specific details are set forth to provide a thorough understanding of this application. However, this application can be implemented in a plurality of other ways different from those described herein, and a person skilled in the art can make similar improvements without departing from the essence of this application. Therefore, this application is not limited by the specific implementations disclosed below.

In the description of this application, it should be understood that when terms such as “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, “axial”, “radial”, and “circumferential” appear, orientations or positional relationships indicated by these terms are based on orientations or positional relationships shown in the accompanying drawings. The terms are merely intended to facilitate the description of this application and simplify the description, rather than indicating or implying that the apparatuses or components referred to in this application need to have specific orientations, or be constructed and operated in a specific orientation. Therefore, the terms shall not be construed as limitations on this application.

In addition, when terms such as “first” and “second” appear, these terms are merely for the purpose of description, and shall not be understood as any indication or implication of relative importance or any implicit indication of a quantity of indicated technical features. Therefore, a feature defined by “first” or “second” may explicitly or implicitly include at least one feature. In the description of this application, when the term “a plurality of” appears, the term “a plurality of” means at least two, for example, two or three, unless otherwise clearly and specifically defined.

In this application, unless otherwise clearly specified and defined, when terms such as “mount”, “connect”, “join”, and “fasten” appear, these terms should be understood in a broad sense. For example, the terms may refer to a fixed connection, a detachable connection, or integration, may refer to a mechanical connection or an electrical connection, or may refer to a direct connection, an indirect connection through an intermediate medium, internal communication between two components, or an interaction relationship between two components, unless otherwise clearly defined. For a person of ordinary skill in the art, specific meanings of the foregoing terms in this application may be understood based on specific circumstances.

In this application, unless otherwise clearly specified and defined, when descriptions such as a first feature being “on” or “under” a second feature appear, the descriptions may mean that the first feature and the second feature are in direct contact, or that the first feature and the second feature are in indirect contact through an intermediate medium. Moreover, the first feature being “above”, “over”, or “on top of” the second feature may mean that the first feature is directly above or obliquely above the second feature, or may merely indicate that the first feature is at a higher horizontal level than the second feature. The first feature being “below”, “under”, or “beneath” the second feature may mean that the first feature is directly below or obliquely below the second feature, or may merely indicate that the first feature is at a lower horizontal level than the second feature.

As described in the background, a co-packaged optics (Co-packaged Optics, CPO) technology can shorten a distance between a switching chip and an optical chip and integrate the two chips on a same substrate, thereby reducing an interconnection distance and achieving high-speed signal transmission and low system power consumption. However, in the CPO technology, continuously reducing the interconnection distance between the high-power switching chip and the optical chip or integrating the two chips on the same substrate inevitably leads to a thermal crosstalk problem, especially because the optical chip is highly temperature-sensitive. For example, in the optical chip, an optical component such as a laser or a detector is temperature-sensitive, and an allowable junction temperature is usually −40 °C to 85 °C An electronic component in the switching chip has strong resistance to a high temperature, and an allowable junction temperature is usually −55 °C to 125 °C (for some switching chips, the allowable junction temperature may even reach 150 °C). A contradiction in heat dissipation between the optical chip and the switching chip lies in that power consumption of the switching chip may account for more than 70% of total power consumption of the CPO, and the switching chip is a primary heat source, whereas a maximum allowable temperature of the optical chip is lower than a maximum allowable temperature of the switching chip. The temperature herein refers to a junction temperature or a case temperature, but is not specifically limited. Therefore, how to balance the temperature sensitivity and power consumption of the optical chip and the switching chip is an urgent problem to be resolved.

Currently, liquid cooling is used for heat dissipation of the CPO. However, in a current layout design of a liquid cooling pipe, liquid flows through the high-power switching chip first, causing a problem of thermal crosstalk to the optical chip. A significant temperature rise may lead to degradation of optical signal quality, which is unfavorable to performance of the entire CPO system. Certainly, not only the CPO system has the foregoing problem, but also packaging of a large-cache processor has the foregoing problem. A high bandwidth memory (High Bandwidth Memory, HBM) has large thermal resistance, resulting in a low allowable temperature and great difficulty in heat dissipation.

In view of the foregoing problems, embodiments of this application provide a heat dissipation apparatus and a chip co-packaging system, which can enable a coolant to preferentially cool a more temperature-sensitive first heat-generating component, effectively avoid thermal crosstalk caused by high heat of a second heat-generating component to the first heat-generating component, ensure that the first heat-generating component is at a maximum allowable temperature (junction temperature or case temperature), and stabilize quality of the first heat-generating component, thereby improving data transmission performance of the entire chip co-packaging system.

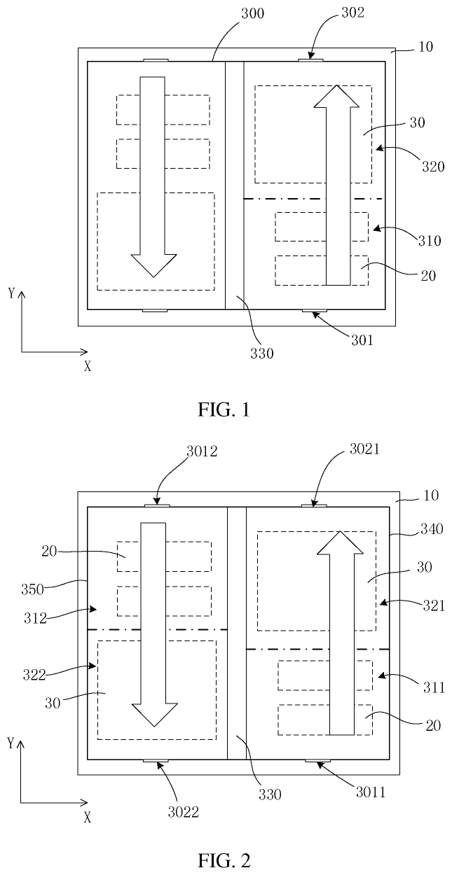

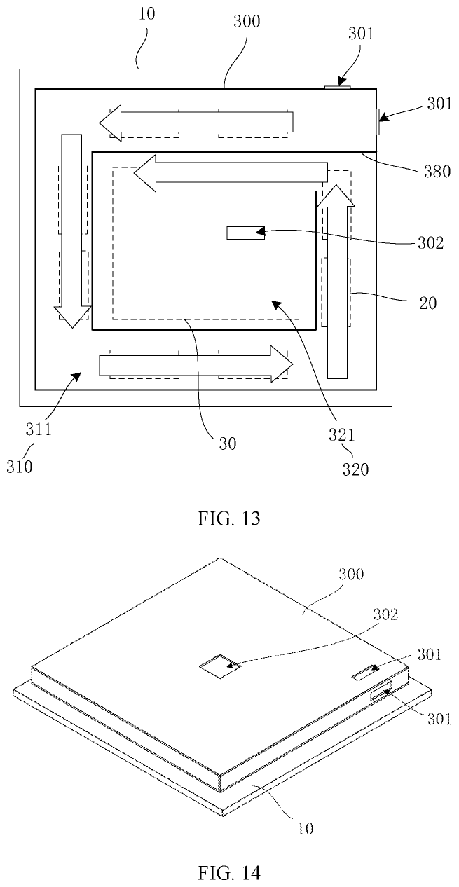

Refer to FIG. 1, FIG. 2, and FIG. 13. FIG. 1 is a schematic diagram of a heat dissipation principle of a heat dissipation apparatus according to some embodiments of this application. FIG. 2 is a schematic diagram of a heat dissipation principle of a first sub-cold plate and a second sub-cold plate according to some embodiments of this application. FIG. 13 is a schematic diagram of a heat dissipation principle of a heat dissipation apparatus according to some other embodiments of this application. A heat dissipation apparatus provided in an embodiment of this application is used for dissipating heat from a first heat-generating component 20 and a second heat-generating component 30 on a substrate 10, where a maximum allowable temperature of the first heat-generating component 20 is lower than a maximum allowable temperature of the second heat-generating component 30; and the heat dissipation apparatus may include a cold plate 300.

The cold plate 300 is in thermal contact with the first heat-generating component 20 and the second heat-generating component 30. The cold plate 300 includes a first heat dissipation portion 310 and a second heat dissipation portion 320. The first heat dissipation portion 310 is provided with a liquid inlet 301, where the liquid inlet 301 is configured to inject a coolant into the first heat dissipation portion 310 to dissipate heat from the first heat-generating component 20; and the second heat dissipation portion 320 is in fluid communication with the first heat dissipation portion 310 and is provided with a liquid outlet 302, where the second heat dissipation portion 320 is configured to receive the coolant from the first heat dissipation portion 310 to dissipate heat from the second heat-generating component 30, and to discharge the coolant from the liquid outlet 302.

It may be understood that the first heat-generating component 20 on the substrate 10 may be an optical chip, and the second heat-generating component 30 may be a switching chip, where a maximum allowable temperature of the optical chip is lower than a maximum allowable temperature of the switching chip. Certainly, the temperature herein may be a junction temperature or a case temperature, but is not specifically limited, that is, the first heat-generating component 20 is a thermally sensitive chip, and the second heat-generating component 30 is a high-power (non-thermally-sensitive) chip. Certainly, the substrate 10 may include a plurality of optical chips and a plurality of switching chips, and there are a plurality of arrangements for the plurality of optical chips and the plurality of switching chips. For example, a substrate 10 includes a plurality of groups of optical chips and switching chips (one group includes one switching chip and two optical chips) arranged in arrays, or a substrate 10 includes a switching chip arranged in the middle and a plurality of optical chips arranged at an outer periphery of the switching chip. A specific arrangement is not limited herein.

A design of the heat dissipation apparatus in this example needs to be combined with the arrangement of optical chips and switching chips on the substrate 10, to ensure that the coolant in the heat dissipation apparatus first flows through the optical chips (referring to thermally sensitive chips) and then through the switching chips (referring to high-power chips or non-thermally-sensitive chips), so as to avoid thermal crosstalk caused by high heat of the switching chips to the optical chips, and ensure that the optical chips are in a low-temperature environment, thereby stabilizing optical signal quality, while achieving effective heat dissipation for chips with different heat generation requirements and improving overall heat dissipation efficiency of a system.

In a specific implementation, one or more cold plates 300 may be designed based on the arrangement of the first heat-generating component 20 and the second heat-generating component 30 on the substrate 10. A lower surface of the cold plate 300 (the first heat dissipation portion 310 and the second heat dissipation portion 320) is used for direct thermal contact with upper surfaces of the first heat-generating component 20 and the second heat-generating component 30. Certainly, the lower surface of the cold plate 300 may abut against the first heat-generating component 20 and the second heat-generating component 30 as closely as possible to ensure good heat conduction.

In an embodiment, the first heat-generating component 20 and the second heat-generating component 30 may be integrated on the same substrate 10. Dimensions of the first heat-generating component 20 and the second heat-generating component 30 may be different, leading to inconsistent heights of the first heat-generating component 20 and the second heat-generating component 30 on the substrate 10. In view of this problem, in addition to the foregoing manner of direct thermal contact, the lower surface of the cold plate 300 may also closely abut against one of the first heat-generating component 20 and the second heat-generating component 30, and the other one of the first heat-generating component 20 and the second heat-generating component 30 is in indirect contact (another example of thermal contact) with the lower surface of the cold plate 300 through a thermally conductive medium 40 (thermal grease), as shown in FIG. 6. In this way, dissipated heat can also be effectively transferred to the cold plate 300 in a timely manner. Certainly, in addition to the foregoing manner, a shape of the lower surface of the cold plate 300 may also be designed based on the heights of the first heat-generating component 20 and the second heat-generating component 30, for example, designed as a stepped shape, so that the lower surface of the cold plate 300 abuts against both the first heat-generating component 20 and the second heat-generating component 30, thereby ensuring good heat conduction.

This embodiment further provides an external coolant supply device. The coolant supply device may be connected to the liquid inlet 301 of the cold plate 300 through a pipeline, thereby providing a low-temperature coolant for the cold plate 300. A specific heat dissipation process may be as follows: The coolant flows from the liquid inlet 301 into the first heat dissipation portion 310. In the first heat dissipation portion 310, the coolant fully absorbs heat emitted by the first heat-generating component 20 (optical chip), and the temperature of the coolant rises. Then, after absorbing the heat, the coolant flows into the second heat dissipation portion 320 and continues to absorb heat emitted by the second heat-generating component 30 (switching chip). Finally, the temperature-increased coolant flows out of the liquid outlet 302 and is processed by an external recovery device, thereby completing a heat dissipation cycle.

It should be noted that because the allowable temperature (junction temperature or case temperature) of the first heat-generating component 20 (optical chip) is low and power consumption thereof is also low, the temperature rise of the coolant after absorbing the heat emitted by the first heat-generating component 20 is relatively slow, that is, the coolant having absorbed the heat can still fully absorb a large amount of heat emitted by the second heat-generating component 30 in the second heat dissipation portion 320.

In this embodiment, the first heat dissipation portion 310 and the second heat dissipation portion 320 disposed inside the cold plate 300 may be microchannel structures. For example, a large quantity of microchannels (ranging from tens of micrometers to hundreds of micrometers) may be formed inside the cold plate 300 through photolithography, etching, or the like. The coolant flows through the microchannels to exchange heat with the first heat-generating component 20 and the second heat-generating component 30. Shapes of the microchannels may be linear, serpentine, or other shapes, and may be specifically designed based on the arrangement of the first heat-generating component 20 and the second heat-generating component 30, and actual heat dissipation conditions (residence time). This is not specifically limited. Because a microchannel structure has a large specific surface area, the microchannel structure can significantly enhance efficiency of heat exchange between the coolant and a heat-generating component to take away more heat, and the microchannel structure can form a more uniform temperature distribution, which helps reduce local hot spots of the heat-generating component and improve uniformity of heat dissipation.

Certainly, the foregoing heat dissipation portions may also be liquid chambers, where two liquid chambers correspond to the first heat-generating component 20 and the second heat-generating component 30 respectively. The coolant flowing in from the liquid inlet 301 first enters a liquid chamber corresponding to the first heat-generating component 20, and after heat exchange, flows into a liquid chamber corresponding to the second heat-generating component 30, undergoes heat exchange again, and is finally discharged from the liquid outlet 302. A specific structure and arrangement of the liquid chambers may be understood based on the following content, and are not described herein.

In addition, as shown in FIG. 8, a flow regulating valve 400 and a flow rate controller 500 may also be installed on the coolant supply pipeline, so that the flow regulating valve 400 and the flow rate controller 500 are controlled and adjusted based on real-time heat generation conditions of the first heat-generating component 20 and the second heat-generating component 30. A corresponding adjustment manner includes: when the heat generated by the first heat-generating component 20 and the second heat-generating component 30 is high, the flow regulating valve 400 and the flow rate controller 500 may be adjusted to increase a flow rate and flow velocity of the coolant, so as to enhance a heat dissipation effect; or when the heat generated by the first heat-generating component 20 and the second heat-generating component 30 is normal or low, the flow regulating valve 400 and the flow rate controller 500 are adjusted to reduce a flow rate and flow velocity, so as to save energy and reduce load on the cooling system. This arrangement enables dynamic adjustment of heat dissipation based on actual heat generation conditions of the heat-generating components, thereby optimizing heat dissipation performance and improving adaptability of the heat dissipation apparatus.

In embodiments of this application, effective heat conduction is ensured by bringing the cold plate 300 into close thermal contact with the first heat-generating component 20 and the second heat-generating component 30. Furthermore, the first heat dissipation portion 310 and the second heat dissipation portion 320 in fluid communication with each other are disposed inside the cold plate 300. The coolant flows from the liquid inlet 301 into the first heat dissipation portion 310. In the first heat dissipation portion 310, the coolant fully absorbs the heat emitted by the first heat-generating component 20. After absorbing the heat, the coolant subsequently flows into the second heat dissipation portion 320. In the second heat dissipation portion 320, the coolant continues to absorb the heat emitted by the second heat-generating component 30, and then the temperature-increased coolant flows out of the liquid outlet 302. This arrangement enables the coolant to preferentially cool the more temperature-sensitive first heat-generating component 20, ensures that the first heat-generating component 20 is in a low-temperature environment, and stabilizes signal quality of the first heat-generating component 20, thereby improving data transmission performance of the substrate 10. In addition, this arrangement can effectively prevent thermal crosstalk-induced overheating of the first heat-generating component 20 caused by the heat emitted by the second heat-generating component 30, and can also achieve effective heat dissipation of the second heat-generating component 30 while ensuring performance of the first heat-generating component 20, thereby helping improve heat dissipation efficiency of the substrate 10.

A specific structure of the heat dissipation apparatus provided in embodiments of this application is hereinafter described with reference to FIG. 1 to FIG. 17.

As shown in FIG. 1 and FIG. 2, in some embodiments, a first liquid chamber 311 is formed inside the first heat dissipation portion 310, a second liquid chamber 321 is formed inside the second heat dissipation portion 320, and the first liquid chamber 311 and the second liquid chamber 321 are in fluid communication with each other; and the liquid inlet 301 allows the coolant to flow into the first liquid chamber 311, and the liquid outlet 302 allows the coolant to flow out of the second liquid chamber 321.

Specifically, the cold plate 300 may be manufactured by an integral forming process. The first liquid chamber 311 and the second liquid chamber 321, which are in communication with each other, may be formed inside the cold plate 300 by machining. The first liquid chamber 311 and the second liquid chamber 321 may also be understood as space formed by dividing an inner cavity of the cold plate 300. Sizes of the two liquid chambers may be the same or different, and are specifically set based on dimensions and shapes of corresponding heat-generating components, and are not specifically limited herein. The liquid inlet 301 is provided at the first liquid chamber 311, and the liquid outlet 302 is provided at the second liquid chamber 321, to ensure that the coolant entering from the liquid inlet 301 preferentially enters the first liquid chamber 311, then flows from the first liquid chamber 311 into the second liquid chamber 321, and finally is discharged from the liquid outlet 302 at the second liquid chamber 321.

A CPO system is used as an example. The cold plate 300 is mounted on a side of the optical chip and the switching chip facing away from the substrate 10. The first liquid chamber 311 corresponds to a position of the optical chip, and the second liquid chamber 321 corresponds to a position of the switching chip. A specific arrangement of the first liquid chamber 311 and the second liquid chamber 321 may be set based on an arrangement of the optical chip and the switching chip. If the optical chip and the switching chip are arranged side by side, the first liquid chamber 311 and the second liquid chamber 321 are arranged side by side. If the optical chip is arranged at an outer periphery of the switching chip, the first liquid chamber 311 is also correspondingly arranged at an outer periphery of the second liquid chamber 321. For example, the first liquid chamber may be arranged in a rectangular annular shape around the outer periphery of the second liquid chamber 321, so that after fully absorbing the heat emitted by the optical chip, the coolant flows into the second liquid chamber 321. A specific arrangement form of the first liquid chamber 311 and the second liquid chamber 321 is not limited herein.

Certainly, the first heat dissipation portion 310 further includes a plurality of heat pipes or vapor chambers (Vapor Chambers, VCs) disposed in the first liquid chamber 311. Heat dissipation principles of the vapor chambers and heat pipes are basically the same. A heat pipe is used as an example for description. The heat pipe, as a heat transfer element with high thermal conductivity, is usually filled with a working medium, such as pure water or ammonia. An evaporation end of the heat pipe may be in close contact with the first heat-generating component 20. For example, the evaporation end of the heat pipe may be tightly attached to a surface of the cold plate 300 near the first heat-generating component 20, or the heat pipe may pass through a surface of the cold plate 300 near the first heat-generating component 20; and a condensation end needs to be immersed in the first liquid chamber 311 to exchange heat with the coolant in the first liquid chamber 311. Similarly, the second heat dissipation portion 320 further includes a plurality of heat pipes disposed in the second liquid chamber 321. A specific working principle of the heat pipes may be understood based on a related technology, and is not described herein again. Due to high thermal conductivity of the heat pipes, the heat pipes can quickly transfer the heat from the heat-generating component to the coolant, thereby increasing a heat dissipation speed.

In this embodiment, the arrangement of the first liquid chamber 311 and the second liquid chamber 321 in the cold plate 300 can make a flow path of the coolant clearer, which is beneficial for improving heat dissipation efficiency. In addition, this structure is easy to manufacture and maintain, and reduces production costs.

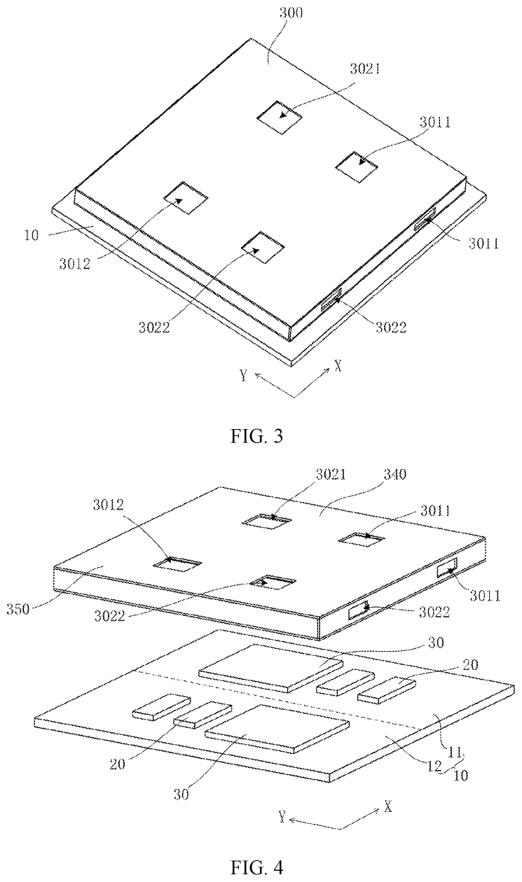

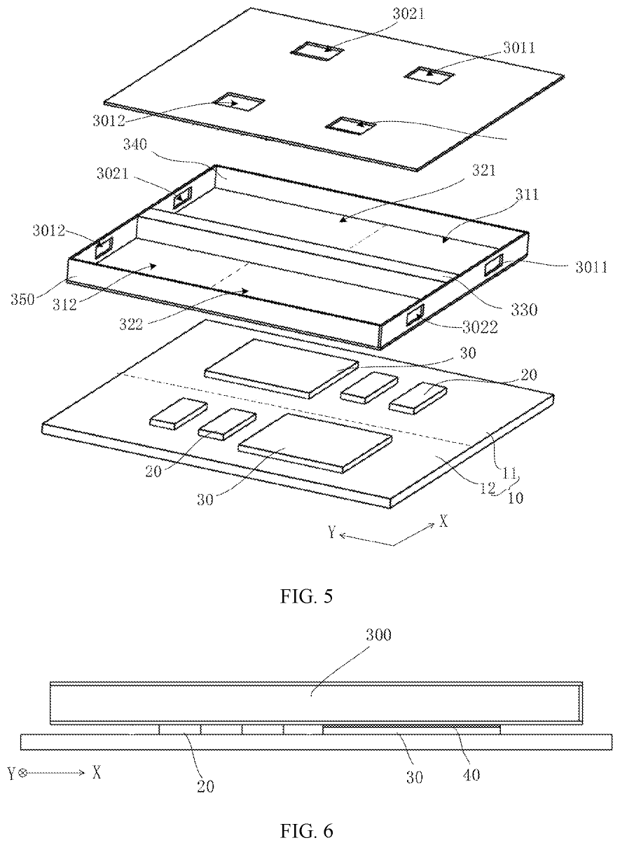

As shown in FIG. 3 to FIG. 5, FIG. 3 is a schematic diagram of an overall structure of a heat dissipation apparatus according to some embodiments of this application. FIG. 4 is a schematic exploded view of a structure of a heat dissipation apparatus and a substrate according to some embodiments of this application. FIG. 5 is a schematic diagram of a structure of a correspondence between a first sub-cold plate, a second sub-cold plate, and a substrate according to some embodiments of this application. In some embodiments, the cold plate 300 includes a first sub-cold plate 340 and a second sub-cold plate 350, and a partition member 330 is disposed between the first sub-cold plate 340 and the second sub-cold plate 350. The first sub-cold plate 340 includes the first liquid chamber 311 and the second liquid chamber 321, the first sub-cold plate 340 is correspondingly provided with a first liquid inlet 3011 and a first liquid outlet 3021, the first liquid inlet 3011 allows the coolant to flow into the first liquid chamber 311, and the first liquid outlet 3021 allows the coolant to flow out of the second liquid chamber 321. The second sub-cold plate 350 includes a third liquid chamber 312 and a fourth liquid chamber 322, the third liquid chamber 312 and the fourth liquid chamber 322 are in fluid communication with each other, the second sub-cold plate 350 is correspondingly provided with a second liquid inlet 3012 and a second liquid outlet 3022, the second liquid inlet 3012 allows the coolant to flow into the third liquid chamber 312, and the second liquid outlet 3022 allows the coolant to flow out of the fourth liquid chamber 322.

Specifically, based on the layout and heat dissipation requirements of heat-generating components, the cold plate 300 may be properly divided into a plurality of sub-cold plates 300. In this example, the division of the cold plate 300 into the first sub-cold plate 340 and the second sub-cold plate 350 is used as an example for description. The division of the first sub-cold plate 340 and the second sub-cold plate 350 may be achieved by arranging the partition member 330 in the cold plate 300, that is, based on arrangement positions of the heat-generating components, the partition member 330 is properly positioned to divide the cold plate 300 (specifically, internal space of the cold plate 300) into the first sub-cold plate 340 and the second sub-cold plate 350, and the first sub-cold plate 340 and the second sub-cold plate 350 are independent and not in communication with each other. In other words, each of the first sub-cold plate 340 and the second sub-cold plate 350 is independently provided with a liquid inlet 301 and a liquid outlet 302, and connected to a coolant supply pipeline and a recovery pipeline. In this example, the liquid inlet 301 and the liquid outlet 302 corresponding to the first sub-cold plate 340 are configured as the first liquid inlet 3011 and the first liquid outlet 3021, and the liquid inlet 301 and the liquid outlet 302 corresponding to the second sub-cold plate 350 are configured as the second liquid inlet 3012 and the second liquid outlet 3022.

More specifically, in the CPO system, the substrate 10 is divided into a first substrate 11 and a second substrate 12 along an X direction. Each of the first substrate 11 and the second substrate 12 integrates one switching chip and two optical chips, and a first switching chip and two optical chips are arranged sequentially along a Y direction, where the Y direction is perpendicular to the X direction. Because both the first substrate 11 and the second substrate 12 integrate optical chips and switching chips, it is necessary to dissipate heat from the chips on the first substrate 11 and the second substrate 12 separately. Based on the division of the substrate 10, the cold plate 300 may be divided into the first sub-cold plate 340 and the second sub-cold plate 350, the first sub-cold plate 340 corresponds to the first substrate 11, and the second sub-cold plate 350 corresponds to the second substrate 12. The first liquid chamber 311 and the second liquid chamber 321 in the first sub-cold plate 340 are arranged along the Y direction. Similarly, the third liquid chamber 312 and the fourth liquid chamber 322 in the second sub-cold plate 350 are also arranged along the Y direction.

In this embodiment, corresponding sub-cold plates 300 are arranged for different chip grouping regions, thereby achieving region-based heat dissipation management. In addition, the first sub-cold plate 340 and the second sub-cold plate 350 that are independent of each other can flexibly adjust the coolant flow rate and fluid based on heat generation conditions of chips in different regions, so that heat dissipation is better targeted and more effective. In addition, the arrangement of the partition member 330 can avoid thermal crosstalk between adjacent sub-cold plates 300.

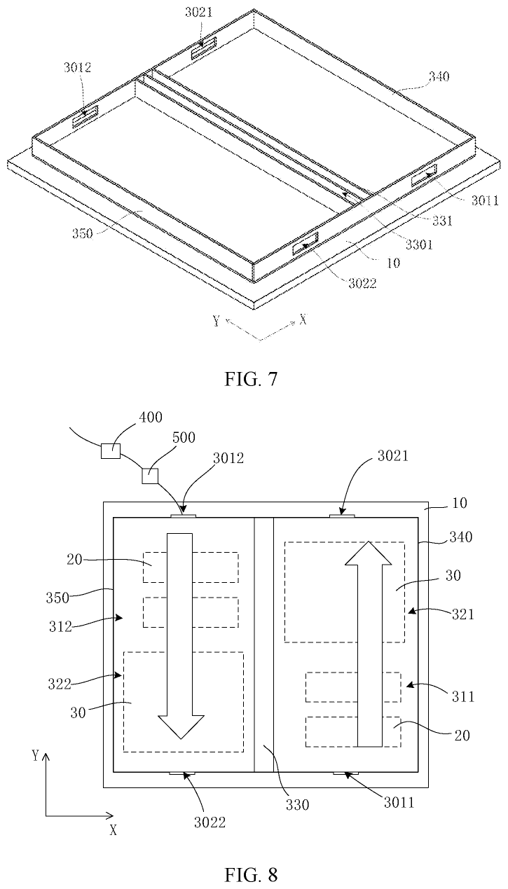

As shown in FIG. 7, FIG. 7 is a schematic diagram of a structure of a partition member in a cold plate according to some embodiments of this application. In some embodiments, the partition member 330 includes at least two partition plates 331, and two adjacent partition plates 331 and a side wall of the cold plate 300 enclose a thermal insulation chamber 3301.

Specifically, two partition plates 331 may be disposed inside the cold plate 300, so that the two partition plates 331 and the side wall of the cold plate 300 enclose one thermal insulation chamber 3301. Certainly, three partition plates 331 may also be disposed inside the cold plate 300, so that the three partition plates 331 and the side wall of the cold plate 300 enclose two thermal insulation chambers 3301. A specific quantity of partition plates 331 is not limited herein. The thermal insulation chamber 3301 enclosed by the adjacent partition plates 331 and the side wall of the cold plate 300 may be filled with air, or evacuated, or filled with a material having low thermal conductivity, to prevent mutual heating of fluids between adjacent flow channel regions. For example, in the CPO system, the thermal insulation chamber 3301 can effectively block heat transfer between different sub-cold plates 300, ensuring highly efficient heat dissipation of the coolant in respective flow channels. This arrangement enhances a thermal isolation effect between the first sub-cold plate 340 and the second sub-cold plate 350, further reduces a possibility of thermal crosstalk, and improves the heat dissipation performance and stability of the entire heat dissipation apparatus.

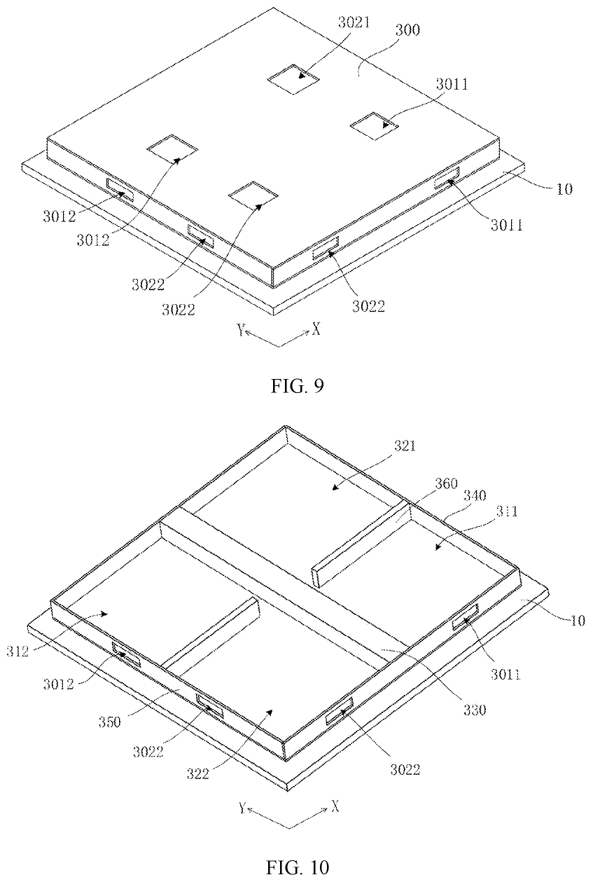

As shown in FIG. 3 and FIG. 9, FIG. 9 is a schematic diagram of a structure of a plurality of liquid inlets and a plurality of liquid outlets in a cold plate according to some embodiments of this application. In some embodiments, the first liquid inlet 3011 is disposed on at least one of a side of the first sub-cold plate 340 facing away from the substrate 10 or a side adjacent to the substrate 10; and the second liquid inlet 3012 is disposed on at least one of a side of the second sub-cold plate 350 facing away from the substrate 10 or a side adjacent to the substrate 10.

Specifically, each of the first sub-cold plate 340 and the second sub-cold plate 350 may be provided with one or more liquid inlets 301, and the position of the liquid inlet 301 is not limited. The liquid inlet 301 may be provided on a side of the cold plate 300 facing away from the substrate 10, or on a side adjacent to the substrate 10, where the side adjacent to the substrate 10 refers to a side of the first sub-cold plate 340 or the second sub-cold plate 350 (referring to the side wall of the first sub-cold plate 340 or the second sub-cold plate 350) perpendicular to a main surface of the substrate 10. For example, first liquid inlets 3011 are provided on a side of the first sub-cold plate 340 facing away from the substrate 10, and on a side wall of the first sub-cold plate 340 adjacent to the substrate 10; and second liquid inlets 3012 are provided on a side of the second sub-cold plate 350 facing away from the substrate 10, and on a side wall of the second sub-cold plate 350 adjacent to the substrate 10. Certainly, positions and quantities of the first liquid inlets 3011 and the second liquid inlets 3012 also need to be comprehensively considered based on a spatial layout of the substrate 10 (for example, CPO) and convenience of coolant pipeline connection, to facilitate the connection and arrangement of coolant pipelines, while ensuring sufficient flow of the coolant in a flow channel.

As shown in FIG. 3 and FIG. 9, in an example, the first liquid outlet 3021 is disposed on at least one of the side of the first sub-cold plate 340 facing away from the substrate 10 or the side adjacent to the substrate 10; and the second liquid outlet 3022 is disposed on at least one of the side of the second sub-cold plate 350 facing away from the substrate 10 or the side adjacent to the substrate 10.

Specifically, based on the same principle as the arrangement of the first liquid inlets 3011 and the second liquid inlets 3012, quantities and positions of the first liquid outlets 3021 and the second liquid outlets 3022 are not limited, to better adapt to structures of different substrates 10 (for example, CPO) and improve versatility and installability of the heat dissipation apparatus.

In addition, for example, the first sub-cold plate 340 may be provided with a plurality of first liquid inlets 3011 and a plurality of first liquid outlets 3021. A correspondence between the plurality of first liquid inlets 3011 and the plurality of first liquid outlets 3021 may be that one first liquid inlet 3011 and one first liquid outlet 3021 are provided at each of the two ends along the Y direction, or one first liquid inlet 3011 and one first liquid outlet 3021 are provided on the side wall of the first sub-cold plate 340 along the Y direction, or one first liquid inlet 3011 and one first liquid outlet 3021 are provided on the side of the first sub-cold plate 340 facing away from the substrate 10. The foregoing first liquid inlets 3011 and first liquid outlets 3021 provided at different positions on the first sub-cold plate 340 may be used fixedly or in combination, and are not specifically limited herein.

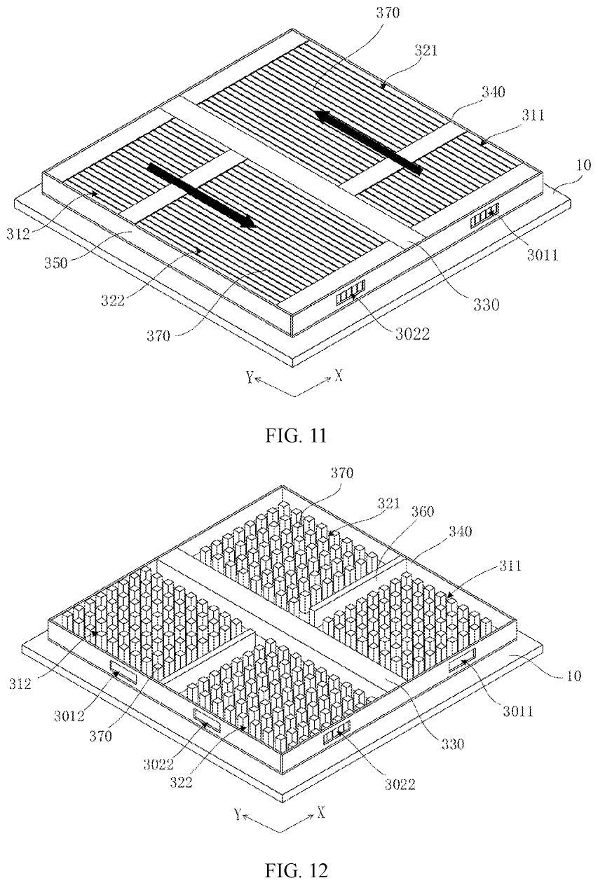

As shown in FIG. 10, FIG. 10 is a schematic diagram of a structure of a baffle plate in a cold plate according to some embodiments of this application. In some embodiments, at least one baffle plate 360 is disposed between the first liquid chamber 311 and the second liquid chamber 321, and the at least one baffle plate 360 is configured to form a flow path of the coolant from the first liquid chamber 311 to the second liquid chamber 321.

Specifically, the arrangement of the baffle plate 360 mainly changes the flow path of the coolant, for example, including extending a flow channel length and increasing flow time of the coolant to enhance heat exchange. When the first liquid chamber 311 and the second liquid chamber 321 are arranged along the Y direction, the baffle plate 360 is disposed between the first liquid chamber 311 and the second liquid chamber 321 and extends along the X direction. The baffle plate 360 may define one channel between the first liquid chamber 311 and the second liquid chamber 321 (one end of the baffle plate 360 is connected to the side wall of the cold plate 300), or may define two channels.

In addition, a plurality of baffle plates 360 may be arranged at intervals in a staggered manner along the Y direction to force the coolant to flow along an S-shaped path, thereby extending the flow time to enhance heat exchange. Certainly, a shape of the baffle plate 360 is not limited to a flat plate, and may also be a corrugated plate or an arcuate plate. This is not specifically limited.

It should be noted that when only one baffle plate 360 is disposed for the first liquid chamber 311 and the second liquid chamber 321, a channel formed by the baffle plate 360 and the side wall of the cold plate 300 or the partition plate 331 needs to be away from the position of the liquid inlet 301 and/or the liquid outlet 302, to ensure that the fluid flowing in from the liquid inlet 301 needs to flow a longer distance in the first liquid chamber 311 and the second liquid chamber 321.

In addition, in this example, the baffle plate 360 may be disposed in the first sub-cold plate 340, or in the second sub-cold plate 350, or in both the first sub-cold plate 340 and the second sub-cold plate 350. This is not specifically limited herein.

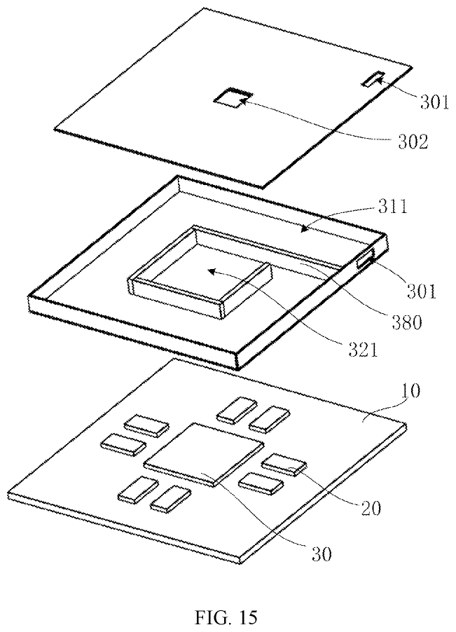

As shown in FIG. 13 to FIG. 15, FIG. 14 is a schematic diagram of an overall structure of a heat dissipation apparatus according to some other embodiments of this application. FIG. 15 is a schematic exploded view of a structure of a heat dissipation apparatus according to some other embodiments of this application. In some embodiments, the heat dissipation apparatus further includes a flow guiding plate 380, the flow guiding plate 380 is disposed inside the cold plate 300 along a preset path to divide space inside the cold plate 300 into a first liquid chamber 311 and a second liquid chamber 321, where the first liquid chamber 311 is located at an outer periphery of the second liquid chamber 321.

Specifically, the flow guiding plate 380 may be made of a thick plate or a thin plate with a heat insulation function to avoid thermal crosstalk between the first liquid chamber 311 and the second liquid chamber 321. The flow guiding plate 380 may be mounted inside the cold plate 300 based on a preset spiral path, and the first liquid chamber 311 surrounds the outer periphery of the second liquid chamber 321, forming a spiral flow channel structure. Certainly, this arrangement of the first liquid chamber 311 and the second liquid chamber 321 is also based on the arrangement of the first heat-generating component 20 and the second heat-generating component 30 in the substrate 10. For example, in the CPO system, a plurality of optical chips are arranged at the outer periphery of the switching chip, and the coolant enters the first liquid chamber 311 from the liquid inlet 301, flows along the spiral flow guiding plate 380 to first dissipate heat from the plurality of optical chips, and finally flows into the second liquid chamber 321 to dissipate heat from the switching chip.

It should be noted that in this example, the first liquid chamber 311 is the first heat dissipation portion 310, and the second liquid chamber 321 is the second heat dissipation portion 320. However, this is not specifically limited.

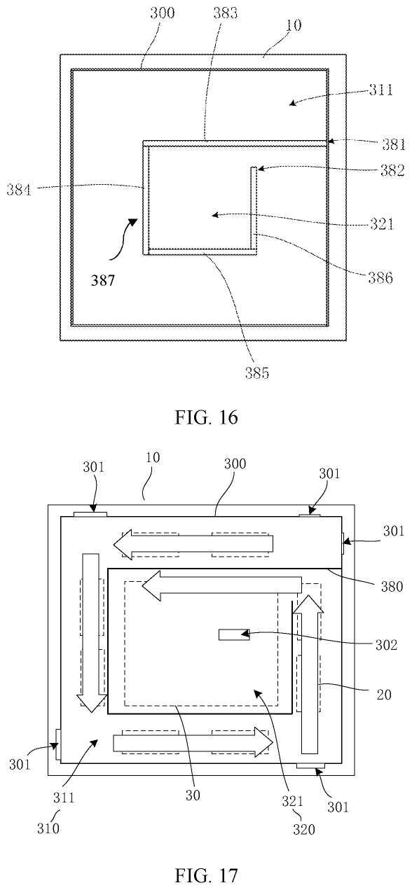

More specifically, for a clearer understanding of the arrangement of the flow guiding plate 380 in the cold plate 300, the shape of the cold plate 300 is defined as a rectangle having a first side, a second side, a third side, and a fourth side. Similarly, as shown in FIG. 16, the flow guiding plate 380 includes a first flow guiding plate 383, a second flow guiding plate 384, a third flow guiding plate 385, and a fourth flow guiding plate 386. One end of the first flow guiding plate 383 is fixed to the fourth side of the cold plate 300, and has a preset distance from the first side, where the distance is a flow channel width; and an extension direction of the first flow guiding plate 383 is parallel to the first side, and the other end of the first flow guiding plate 383 is at a preset distance (flow channel width) from the second side. One end of the second flow guiding plate 384 is fixedly connected to the other end of the first flow guiding plate 383, the second flow guiding plate 384 is arranged parallel to the second side, and the other end of the second flow guiding plate 384 is at a preset distance (flow channel width) from the third side. One end of the third flow guiding plate 385 is fixedly connected to the other end of the second flow guiding plate 384, the third flow guiding plate 385 is arranged parallel to the third side, and the other end of the third flow guiding plate 385 is at a preset distance (flow channel width) from the forth side. One end of the fourth flow guiding plate 386 is fixedly connected to the other end of the third flow guiding plate 385, the fourth flow guiding plate 386 is arranged parallel to the forth side, and the other end of the fourth flow guiding plate 386 is at a preset distance (flow channel width) from the first flow guiding plate 383. A region enclosed by the first flow guiding plate 383, the second flow guiding plate 384, the third flow guiding plate 385, and the fourth flow guiding plate 386 is the second liquid chamber 321.

This arrangement can effectively cool a plurality of temperature-sensitive optical chips located outside the switching chip, and then exchange heat with the high-power switching chip, thereby avoiding thermal crosstalk caused by the heat emitted by the switching chip to the optical chips.

As shown in FIG. 16, in some embodiments, the flow guiding plate 380 includes a starting end 381, a connecting portion 387 and a trailing end 382. The connecting portion 387 connects the starting end 381 to the trailing end 382. The starting end 381 is connected to an inner wall of the cold plate 300. In an embodiment, the connecting portion 387 spirally extends around a center of the cold plate 300; and the coolant spirally flows from the starting end 381 to the trailing end 382 through the connecting portion 387, and flows into the second liquid chamber 321 at the trailing end 382.

Specifically, the starting end 381 of the flow guiding plate 380 may be firmly fixed to the inner wall of the cold plate 300, and the connecting portion 387 spirally extends around the center of the cold plate 300. In the CPO system, the coolant enters from the starting end 381, flows along the spiral path, fully absorbs the heat from the optical chips in the first liquid chamber 311, and finally flows into the second liquid chamber 321 at the trailing end 382 to take away the heat from the switching chip. The spiral deflection design allows the first liquid chamber 311 to fully cover the optical chips, thereby enabling more sufficient heat exchange between the coolant and the chips, while avoiding local hot spots.

As shown in FIG. 13 and FIG. 14, in some embodiments, the liquid inlet 301 is disposed on at least one of a side wall of the cold plate 300 close to the starting end 381 of the flow guiding plate 380 or a surface facing away from the substrate 10; and the liquid outlet 302 is disposed on a surface of the cold plate 300 facing away from the substrate 10.

Specifically, the liquid inlet 301 may be provided on the side wall and/or surface of the cold plate 300 close to the starting end 381 of the flow guiding plate 380, to facilitate rapid entry of the coolant into the first liquid chamber 311. A quantity of liquid inlets 301 is not limited herein, and may be one, two, three, or more. Because the second liquid chamber 321 is surrounded by the first liquid chamber 311, the liquid outlet 302 is disposed on a surface (for example, it may be the surface facing away from the substrate 10) of the cold plate 300 at the second liquid chamber 321. Based on the proper design of the positions of the liquid inlet 301 and the liquid outlet 302, the flow process of the coolant can be optimized, thereby improving operating efficiency of the heat dissipation apparatus and reducing energy consumption.

It should be noted that, because a flow path of the first liquid chamber 311 is long, as shown in FIG. 17, an additional liquid inlet 301 may be provided in the middle of the flow path of the first liquid chamber 311 or on the side wall of the cold plate 300 at a distance from the liquid inlet 301, to ensure heat dissipation of remote optical chips.

As shown in FIG. 11 and FIG. 12, FIG. 11 is a schematic diagram of a structure of a heat sink in a cold plate according to some embodiments of this application. FIG. 12 is a schematic diagram of a structure of a heat sink and a baffle plate in a cold plate according to some embodiments of this application. In some embodiments, the heat dissipation apparatus further includes a heat sink 370, and the heat sink 370 is located in the first liquid chamber 311 and/or the second liquid chamber 321; and the heat sink 370 is disposed on a side wall of the cold plate 300 close to the substrate 10.

Specifically, the heat sink 370 may be understood as an array of heat sink fins. The heat sink 370 may be made of a material with high thermal conductivity, such as copper or aluminum, and may be fixed to the inner wall of the cold plate 300 by welding, riveting, machining, or the like. The heat sink 370 can quickly transfer the heat emitted by the heat-generating component into the liquid chamber, so that the heat is taken away by the coolant flowing between heat sinks 370. The heat sink 370 greatly increases a contact area between the coolant and the heat dissipation portion, and accelerates the heat transfer, thereby improving heat exchange efficiency and ensuring stable operation of the first heat-generating component 20 at a lower temperature.

It should be noted that the heat sink 370 provided in this embodiment may be disposed in any type of cold plate 300 mentioned above. As shown in the figure, in embodiments where the first liquid chamber 311 and the second liquid chamber 321 are in direct communication, the heat sinks 370 are separately disposed in the first liquid chamber 311 and the second liquid chamber 321. As shown in the figure, in embodiments where the baffle plate 360 is disposed between the first liquid chamber 311 and the second liquid chamber 321, the heat sinks 370 may still be separately disposed in the first liquid chamber 311 and the second liquid chamber 321, but it should be noted that an end of each heat sink 370 needs to have a preset distance from the baffle plate 360 to ensure smooth flow of the coolant. Alternatively, the heat sinks 370 provided in this embodiment may also be disposed in the first liquid chamber 311 and the second liquid chamber 321 as shown in the figure, to improve heat exchange efficiency.

As shown in FIG. 6, in some embodiments, a surface of the cold plate 300 facing toward the substrate 10 is a flat surface, where the cold plate 300 abuts against the first heat-generating component 20, and the cold plate 300 is in thermal contact with the second heat-generating component 30 through a heat-conducting member; or the cold plate 300 abuts against the second heat-generating component 30, and the cold plate 300 is in thermal contact with the first heat-generating component 20 through a heat-conducting member.

Specifically, a contact manner between the cold plate 300 and the first heat-generating component 20 and the second heat-generating component 30 in the substrate 10 may be that the first heat-generating component 20 and the second heat-generating component 30 have consistent heights, and the cold plate 300 directly abuts against the heat-generating components. However, dimensions of the first heat-generating component 20 and the second heat-generating component 30 are usually different, resulting in inconsistent heights. In this case, a thermally conductive medium 40 (such as thermal grease or a thermal silicone pad) may be disposed between a lower heat-generating component and the cold plate 300 to fill a small gap and enhance a heat conduction effect.

In addition to the foregoing manner, in an example, a surface of the cold plate 300 facing toward the substrate 10 is a stepped surface, so that the cold plate 300 is in contact with the first heat-generating component 20 and the second heat-generating component 30.

Specifically, a height difference of the stepped surface may match a packaging difference between the first heat-generating component 20 and the second heat-generating component 30, so that the cold plate 300 completely abuts against the first heat-generating component 20 and the second heat-generating component 30, thereby eliminating a contact gap and reducing interfacial thermal resistance.

For some irregularly shaped heat-generating components (chips), a contact surface of the cold plate 300 may be customized to match a shape of a chip surface, thereby ensuring closer contact between the cold plate 300 and the chip, and reducing thermal resistance. This arrangement can significantly improve heat transfer efficiency between the cold plate 300 and the chip, reduce the chip temperature, enhance heat dissipation performance of the heat dissipation apparatus, and ensure stable operation of the chip.

As shown in FIG. 1, FIG. 2, and FIG. 13, in some embodiments, an orthographic projection of the first liquid chamber 311 on the substrate at least partially covers an orthographic projection of the first heat-generating component 20 on the substrate, and an orthographic projection of the second liquid chamber 321 on the substrate at least partially covers an orthographic projection of the second heat-generating component 30 on the substrate.

Specifically, the sizes and positions of the first liquid chamber 311 and the second liquid chamber 321 of the cold plate 300 may be precisely designed based on the dimensions and positions of the first heat-generating component 20 and the second heat-generating component 30, so that the first liquid chamber 311 can completely cover the first heat-generating component 20, and the second liquid chamber 321 can completely cover the second heat-generating component 30. This arrangement can ensure that the coolant fully absorbs the heat emitted by the heat-generating components, thereby avoiding local hot spots.

Based on the same inventive concept, embodiments of this application further provide a chip co-packaging system, including at least one electronic device and the heat dissipation apparatus in the foregoing embodiments. The electronic device includes a substrate 10, a first heat-generating component 20, and a second heat-generating component 30, the first heat-generating component 20 and the second heat-generating component 30 are integrated on the substrate 10, a maximum allowable temperature of the first heat-generating component 20 is lower than a maximum allowable temperature of the second heat-generating component 30, and the temperature includes a junction temperature or a case temperature; and the heat dissipation apparatus is located on a side of the first heat-generating component 20 and the second heat-generating component 30 facing away from the substrate 10 and is in thermal contact with the first heat-generating component 20 and the second heat-generating component 30, and a coolant in the heat dissipation apparatus sequentially flows through the first heat-generating component 20 and the second heat-generating component 30.

It may be understood that the first heat-generating component 20 may be an optical chip, and the second heat-generating component 30 may be a switching chip. The electronic device is formed by integrating a plurality of optical chips and switching chips on the same substrate 10. The heat dissipation apparatus is mounted on the electronic device, so that the cold plate 300 is in close contact with the chips, and the coolant continuously flows into the cold plate 300 through an external circulation system, thereby sequentially dissipating heat from the optical chip and the switching chip. This arrangement effectively resolves a problem of thermal crosstalk between an optical chip and a switching chip in a CPO technology, ensures optical signal quality, and improves performance and stability of the entire chip co-packaging system.

The technical features of the foregoing embodiments may be combined in any way. For brevity of description, not all possible combinations of the technical features of the foregoing embodiments are described. However, as long as there is no contradiction among these combinations of technical features, all the combinations should be considered to fall within the scope described in this specification.

The foregoing embodiments merely represent several implementations of this application, and descriptions thereof are specific and detailed, but should not be construed as a limitation on the scope of this application. It should be noted that a person of ordinary skill in the art may further make several modifications and improvements without departing from the concept of this application, and these modifications and improvements also fall within the protection scope of this application. Therefore, the protection scope of this application should be subject to the appended claims.

1. A heat dissipation apparatus, for dissipating heat from a first heat-generating component and a second heat-generating component disposed on a substrate, wherein a maximum allowable temperature of the first heat-generating component is lower than a maximum allowable temperature of the second heat-generating component; and the heat dissipation apparatus comprises:
a cold plate in thermal contact with the first heat-generating component and the second heat-generating component, wherein the cold plate comprises:
a first heat dissipation portion, provided with a first liquid inlet, wherein the first liquid inlet is configured to allow a first coolant to be injected into the first heat dissipation portion to dissipate heat from the first heat-generating component; and
a second heat dissipation portion, being in fluid communication with the first heat dissipation portion and provided with a first liquid outlet, wherein the second heat dissipation portion is configured to receive the first coolant from the first heat dissipation portion to dissipate heat from the second heat-generating component, and to discharge the first coolant from the first liquid outlet.

2. The heat dissipation apparatus according to claim 1, wherein a first liquid chamber is formed inside the first heat dissipation portion, a second liquid chamber is formed inside the second heat dissipation portion, and the first liquid chamber and the second liquid chamber are in fluid communication with each other.

3. The heat dissipation apparatus according to claim 2, wherein the heat dissipation apparatus further comprises a flow guiding plate the flow guiding plate is disposed inside the cold plate along a preset path to divide space inside the cold plate into the first liquid chamber and the second liquid chamber, wherein the first liquid chamber is located at an outer periphery of the second liquid chamber.

4. The heat dissipation apparatus according to claim 1, wherein the flow guiding plate comprises a starting end, a connecting portion and a trailing end, the starting end is connected to an inner wall of the cold plate, the connecting portion connects the starting end and the trailing end, the flow guiding plate is configured to allow the coolant to spirally flow from the starting end to the trailing end through the connecting portion, and flow into the second liquid chamber at the trailing end.

5. The heat dissipation apparatus according to claim 4, wherein the flow guiding plate spirally extends around a center of the cold plate.

6. The heat dissipation apparatus according to claim 2, wherein the first liquid inlet allows the first coolant to flow into the first liquid chamber, and the first liquid outlet allows the first coolant to flow out of the second liquid chamber.

7. The heat dissipation apparatus according to claim 2, wherein the cold plate comprises a first sub-cold plate and a second sub-cold plate, and a partition member is disposed between the first sub-cold plate and the second sub-cold plate; and
the first sub-cold plate comprises the first liquid chamber and the second liquid chamber, and the first sub-cold plate is correspondingly provided with the first liquid inlet and the first liquid outlet.

8. The heat dissipation apparatus according to claim 7, wherein the second sub-cold plate comprises a third liquid chamber and a fourth liquid chamber, the third liquid chamber and the fourth liquid chamber are in fluid communication with each other, the second sub-cold plate is provided with a second liquid inlet and a second liquid outlet, the second liquid inlet allows a second coolant to flow into the third liquid chamber, and the second liquid outlet allows the second coolant to flow out of the fourth liquid chamber.

9. The heat dissipation apparatus according to claim 7, wherein the partition member comprises at least two partition plates, and two adjacent partition plates and a side wall of the cold plate enclose a thermal insulation chamber.

10. The heat dissipation apparatus according to claim 7, wherein the second liquid inlet is disposed on an opposite side from a side on which the first liquid outlet is located with respect to the partition member, and the second liquid outlet is disposed on an opposite side from a side on which the first liquid inlet is located with respect the partition member.

11. The heat dissipation apparatus according to claim 7, wherein the first liquid inlet is disposed on at least one of a side of the first sub-cold plate facing away from the substrate or a side adjacent to the substrate.

12. The heat dissipation apparatus according to claim 7, wherein the second liquid inlet is disposed on at least one of a side of the second sub-cold plate facing away from the substrate or a side adjacent to the substrate.

13. The heat dissipation apparatus according to claim 7, wherein the first liquid outlet is disposed on at least one of the side of the first sub-cold plate facing away from the substrate or the side adjacent to the substrate.

14. The heat dissipation apparatus according to claim 7, wherein the second liquid outlet is disposed on at least one of a side of the second sub-cold plate facing away from the substrate or a side adjacent to the substrate.

15. The heat dissipation apparatus according to claim 1, wherein a first liquid chamber is formed inside the first heat dissipation portion, a second liquid chamber is formed inside the second heat dissipation portion, the first liquid chamber and the second liquid chamber are in fluid communication with each other, at least one baffle plate is disposed between the first liquid chamber and the second liquid chamber, and the at least one baffle plate is configured to form a flow path of the coolant from the first liquid chamber to the second liquid chamber.

16. The heat dissipation apparatus according to claim 1 wherein an orthographic projection of the first liquid chamber on the substrate at least partially covers an orthographic projection of the first heat-generating component on the substrate, and an orthographic projection of the second liquid chamber on the substrate at least partially covers an orthographic projection of the second heat-generating component on the substrate.

17. A chip co-packaging system, comprising:
at least one electronic device, wherein the electronic device comprises a substrate, a first heat-generating component, and a second heat-generating component, the first heat-generating component and the second heat-generating component are integrated on the substrate, a maximum allowable temperature of the first heat-generating component is lower than a maximum allowable temperature of the second heat-generating component, and the temperature comprises a junction temperature or a case temperature; and
the heat dissipation apparatus according to claim 1, wherein the heat dissipation apparatus is located on a side of the first heat-generating component and the second heat-generating component facing away from the substrate and is in thermal contact with the first heat-generating component and the second heat-generating component, and a coolant in the heat dissipation apparatus sequentially flows through the first heat-generating component and the second heat-generating component.
